(19) United States
(12) Patent Application Publication
(10) Pub. No.: US 2015/0051859 A1
(43) Pub. Date: Feb. 19, 2015

(54) ANALYTIC SYSTEM OF WAFER BIN MAP AND NON-TRANSITORY COMPUTER READABLE MEDIA THEREOF

(71) Applicant: National Tsing Hua University, Hsinchu (TW)

(72) Inventors: Chen-Fu CHIEN, Hsinchu (TW); Chia-Yu HSU, Hsinchu (TW); Wei-Ju CHEN, Hsinchu (TW)

(73) Assignee: National Tsing Hua University, Hsinchu (TW)

(21) Appl. No.: 14/059,904

(22) Filed: Oct. 22, 2013

(30) Foreign Application Priority Data
Aug. 16, 2013 (TW) 102129596

(51) Int. Cl. G01R 31/26

(52) U.S. Cl. CPC G01R 31/2601
USPC 702/81

(57) ABSTRACT

The present invention relates to an analytic system of wafer bin map and a non-transitory computer readable media thereof. The analytic system of wafer bin map includes a wafer bin map input module, a wafer bin map database, a degeneration module, a standardization module, a coordinate transformation module, a defect density characterization module, a test of randomness module, a similarity comparison module, and a pattern evaluation module.

### CROSS-REFERENCE TO RELATED PATENT APPLICATION

This application claims priority to and the benefit of Taiwan Patent Application No. 102129596, filed on Aug. 16, 2013, in the Taiwan Intellectual Property Office, the entire contents of which are hereby incorporated by reference.

### BACKGROUND OF THE INVENTION

1. Field of the Invention

The present invention relates to an analytic system of wafer bin map and non-transitory computer readable media thereof, especially relates to an analytic system of wafer bin map and non-transitory computer readable media thereof using wafer bin map degeneration, standardization, coordinate transformation, test of randomness, calculating a Hausdorff Distance combined with a mountain function, and evaluating its sensitivity and specificity.

2. Description of Related Art

During the wafer manufacturing process, different reasons will cause different defect pattern distributions. Experienced engineers can trace back to possible causes of defects by examining the defect patterns of wafer bin maps. However, hands-on wafer bin map examination consumes lots of time and manpower, and can be influenced by subjective judgments from individuals or by different physiological states such as Asthenopia resulting from long-time working. The examination results of wafer bin maps can differ from person to person and lack a universal frame of reference.

### SUMMARY OF THE INVENTION

In light of the aforementioned problems, the purpose of the present invention is to provide an analytic system of wafer bin map and non-transitory computer readable media thereof using wafer bin map degeneration, standardization, coordinate transformation, test of randomness, calculating a Hausdorff Distance combined with a mountain function, and evaluating its sensitivity and specificity.

According to an aspect of the present invention, an analytic system of wafer bin map includes a wafer bin map input module, a wafer bin map database, a degeneration module, a standardization module, a coordinate transformation module, a defect density characterization module, a test of randomness module, a similarity comparison module, and a pattern evaluation module. The wafer bin map input module provides a wafer bin map. The wafer bin map database stores a plurality of historical wafer bin maps. The degeneration module degenerates the wafer bin map to simplify the wafer bin map. The standardization module constructs a standardized wafer bin map. The coordinate transformation module transforms the coordinates of the standardized wafer bin map to produce a plurality of standardized comparison wafer bin maps. The defect density characterization module characterizes a defect density of the plurality of standardized comparison wafer bin maps to reveal a defect density distribution of the plurality of the standardized comparison wafer bin maps and to produce a plurality of standardized feature wafer bin maps. The test of randomness module implements a test of randomness to the plurality of historical wafer bin maps and removes the plurality of historical wafer bin maps of random patterns to decrease a compared number of the plurality of historical wafer bin maps. The similarity comparison module compares the plurality of standardized feature wafer bin maps with a plurality of standardized feature wafer bin maps corresponding to the plurality of historical wafer bin maps. The pattern evaluation module evaluates a possible match between the standardized wafer bin map and the plurality of historical wafer bin maps, and produces an evaluation result ranking the plurality of historical wafer bin maps according to similarity, sensitivity, and specificity.

Preferably, degenerating the wafer bin map is to calculate a defective weighted sum for each position on the wafer bin map to determine whether or not each position on the wafer bin map is defective.

Preferably, the standardization module maps the wafer bin map to a template, and produces the standardized wafer bin map through a voting mechanism for patching the wafer bin map.

Preferably, the standardized wafer bin map undergoes a polar coordinates transformation and gradually revolves at a fixed angle to produce the plurality of standardized comparison wafer bin maps.

Preferably, the defect density characterization module transforms the plurality of standardized comparison wafer bin maps with a mountain function to reveal the defect density distribution of the plurality of standardized comparison wafer bin maps.

Preferably, the test of randomness module examines the plurality of historical wafer bin maps with log odds ratio and removes the plurality of historical wafer bin maps of random patterns to decrease the compared number of the plurality of historical wafer bin maps.

Preferably, the plurality of standardized feature wafer bin maps corresponding to the plurality of historical wafer bin maps are constructed through a processing of the test of randomness module, the degeneration module, the standardization module, and the defect density characterization module.

Preferably, the similarity comparison module conducts a similarity comparison through calculating a Hausdorff Distance and a comparison weighted sum.

According to another aspect of the present invention, providing a non-transitory computer readable media executing a wafer bin map analyzing process, the process comprises the following steps; providing a wafer bin map by a wafer bin map input module; storing a plurality of historical wafer bin maps by a wafer bin map database; degenerating the wafer bin map to simplify the wafer bin map by a degeneration module; constructing a standardized wafer bin map by a standardization module; transforming the coordinates of the standardized wafer bin map to produce a plurality of standardized comparison wafer bin maps by a coordinate transformation module; characterizing a defect density of the plurality of standardized comparison wafer bin maps to reveal a defect density distribution of the plurality of standardized comparison wafer bin maps and to produce a plurality of standardized feature wafer bin maps by a defect density characterization module; implementing a test of randomness to the plurality of historical wafer bin maps and removing the plurality of historical wafer bin maps of random patterns to decrease a compared number of the plurality of historical wafer bin maps by a test of randomness module; comparing the plurality of standardized feature wafer bin maps with a plurality of standardized feature wafer bin maps corresponding to the plurality of historical wafer bin maps by a similarity comparison module; evaluating a possible match between the standardized wafer bin map and the plurality of historical wafer bin maps, and producing an evaluation result ranking the plurality of historical wafer bin maps according to similarity, sensitivity, and specificity by a pattern evaluation module.

Preferably, degenerating the wafer bin map is to calculate a defective weighted sum for each position on the wafer bin map to determine whether or not each position on the wafer bin map is defective.

Preferably, the standardization module maps the wafer bin map to a template, and produces the standardized wafer bin map through a voting mechanism for patching the wafer bin map.

Preferably, the standardized wafer bin map undergoes a polar coordinates transformation and gradually revolves at a fixed angle to produce the plurality of standardized comparison wafer bin maps.

Preferably, the defect density characterization module transforms the plurality of standardized comparison wafer bin maps with a mountain function to reveal the defect density distribution of the plurality of standardized comparison wafer bin maps.

Preferably, the test of randomness module examines the plurality of historical wafer bin maps with log odds ratio and removes the plurality of historical wafer bin maps of random patterns to decrease the compared number of the plurality of historical wafer bin maps.

Preferably, the plurality of standardized feature wafer bin maps corresponding to the plurality of historical wafer bin maps are constructed through a processing of the test of randomness module, the degeneration module, the standardization module, and the defect density characterization module.

Preferably, the similarity comparison module conducts a similarity comparison through calculating a Hausdorff Distance and a comparison weighted sum.

### BRIEF DESCRIPTION OF THE DRAWINGS

The exemplary embodiment(s) of the present invention will be understood more fully from the detailed description given below and from the accompanying drawings of various embodiments of the invention, which, however, should not be taken to limit the invention to the specific embodiments, but are for explanation and understanding only.

FIG. 1 is an exemplary diagram illustrating a degeneration process of an analytic system of wafer bin map according to an embodiment of the present invention.

FIG. 2 is a flowchart of a standardization process of an analytic system of wafer bin map according to an embodiment of the present invention.

FIG. 3 is an exemplary diagram illustrating the standardization process of an analytic system of wafer bin map according to an embodiment of the present invention.

FIG. 4 is an exemplary diagram illustrating a coordinate transformation of an analytic system of wafer bin map according to an embodiment of the present invention.

FIG. 5 is an exemplary diagram illustrating a defect density distribution of an analytic system of wafer bin map according to an embodiment of the present invention.

FIG. 6 is an exemplary diagram illustrating a similarity comparison process of an analytic system of wafer bin map according to an embodiment of the present invention.

FIG. 7 is an exemplary diagram illustrating a receiver operating characteristic curve of an analytic system of wafer bin map according to an embodiment of the present invention.

FIG. 8 is a line graph of performance index versus rank of an analytic system of wafer bin map according to an embodiment of the present invention.

FIG. 9 is a line graph of method validity examination of an analytic system of wafer bin map according to an embodiment of the present invention.

FIG. 10 is a block diagram of an analytic system of wafer bin map according to an embodiment of the present invention.

FIG. 11 is a flowchart of a wafer bin map analyzing process according to an embodiment of the present invention.

### DETAILED DESCRIPTION OF THE PREFERRED EMBODIMENTS

The technical characteristics, contents, advantages and effects of the present invention will become apparent with the detailed description of the following embodiments and the illustration of related drawings as follows. All figures are drawn for ease of explanation of the basic teachings of the present invention only. The disclosed embodiments may be modified in various ways. The present invention is not limited to the disclosed embodiments. Rather, it covers all modifications, equivalents and substitutes to the disclosed embodiments. It is noteworthy that same numerals are used to represent respective same elements in the following preferred embodiments.

In accordance with the embodiment(s) of the present invention, the components, process steps, and/or data structures described herein may be implemented using various types of operating systems, computing platforms, computer programs, and/or general purpose machines. In addition, those of ordinary skill in the art will recognize that devices of a less general purpose nature, such as hardwired devices, field programmable gate arrays (FPGAs), application specific integrated circuits (ASICs), or the like, may also be used without departing from the scope and spirit of the inventive concepts disclosed herein. Where a method comprising a series of process steps is implemented by a computer or a machine and those process steps can be stored as a series of instructions readable by the machine, they may be stored on a tangible medium such as a computer memory device (e.g., ROM (Read Only Memory), PROM (Programmable Read Only Memory), EEPROM (Electrically Erasable Programmable Read Only Memory), FLASH Memory, Jump Drive, and the like), magnetic storage medium (e.g., tape, magnetic disk drive, and the like), optical storage medium (e.g., CD-ROM, DVD-ROM, paper card and paper tape, and the like) and other known types of program memory.

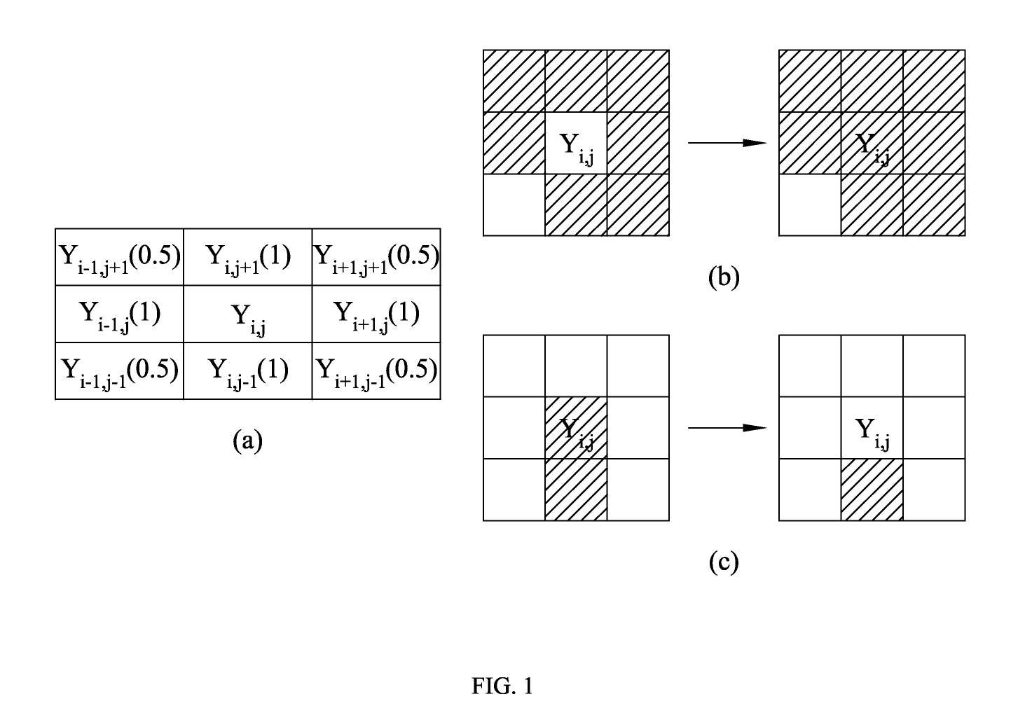

With reference to FIG. 1 for an exemplary diagram illustrating a degeneration process of an analytic system of wafer bin map according to an embodiment of the present invention, a degeneration module sets a location of a bin on a wafer bin map provided by a wafer bin map input module as a center, searches for adjacent 8 bins having a king-move relationship, and assigns each of the adjacent 8 bins with a weight. Bins immediately adjacent to the location of the bin are given a weight with 1. Bins diagonally adjacent to the location of the bin are given a weight with 0.5, as shown by FIG. 1(a). The present invention is not limited to this embodiment. The degeneration module sums up a weight value from the adjacent 8 bins, i.e. a defective weighted sum. If the defective weighted sum is less than a predetermined degeneration threshold value, the bin under examination is regarded as good, as shown by FIG. 1(c). On the contrary, if the defective weighted sum is larger than the predetermined degeneration threshold value, the bin under examination is regarded as defective, as shown by FIG. 1(b). Applying the above procedures to every bin on the wafer bin map repetitively to simplify the wafer bin map provided by the wafer bin map input module.

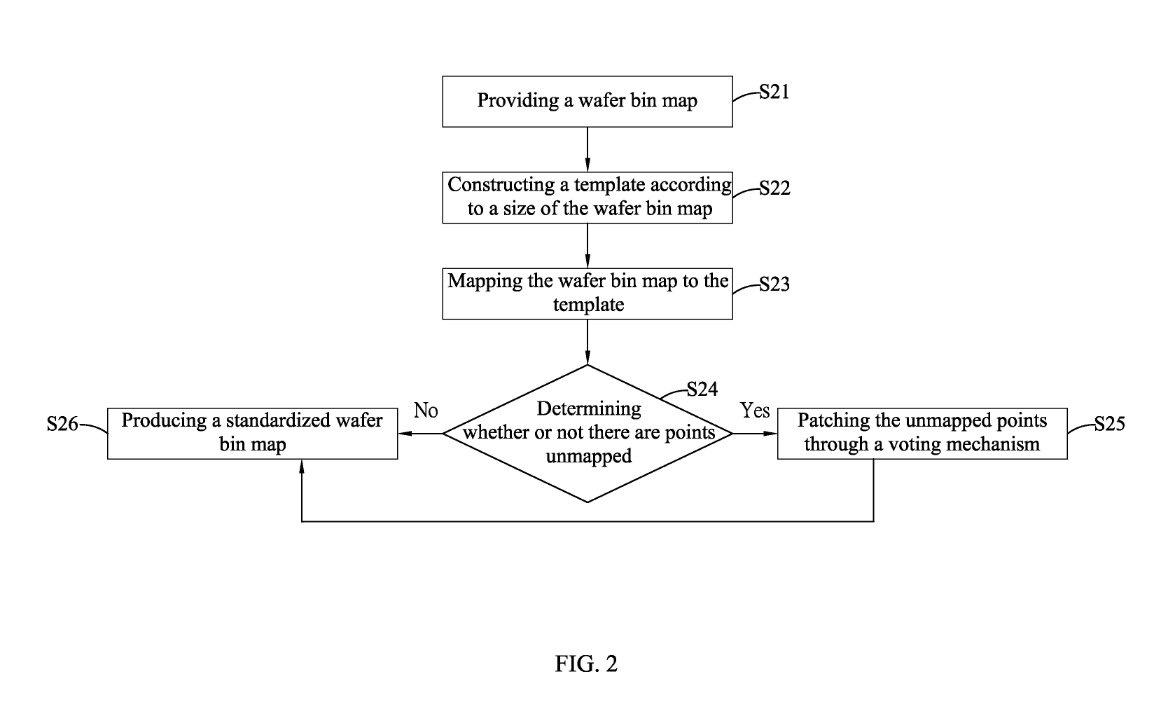

With reference to FIG. 2 for a flowchart of a standardization process of an analytic system of wafer bin map according to an embodiment of the present invention. In step S21, providing a wafer bin map, move on to step S22. In step S22, constructing a template according to a size of the wafer bin map, move on to step S23. In step S23, mapping the wafer bin map to the template, move on to step S24. In step S24, determining whether or not there are points unmapped. If the result is yes, move on to step S25. If the result is no, move on to step S26. In step S25, patching the unmapped points through a voting mechanism, move on to step S26. In step S26, producing a standardized wafer bin map.

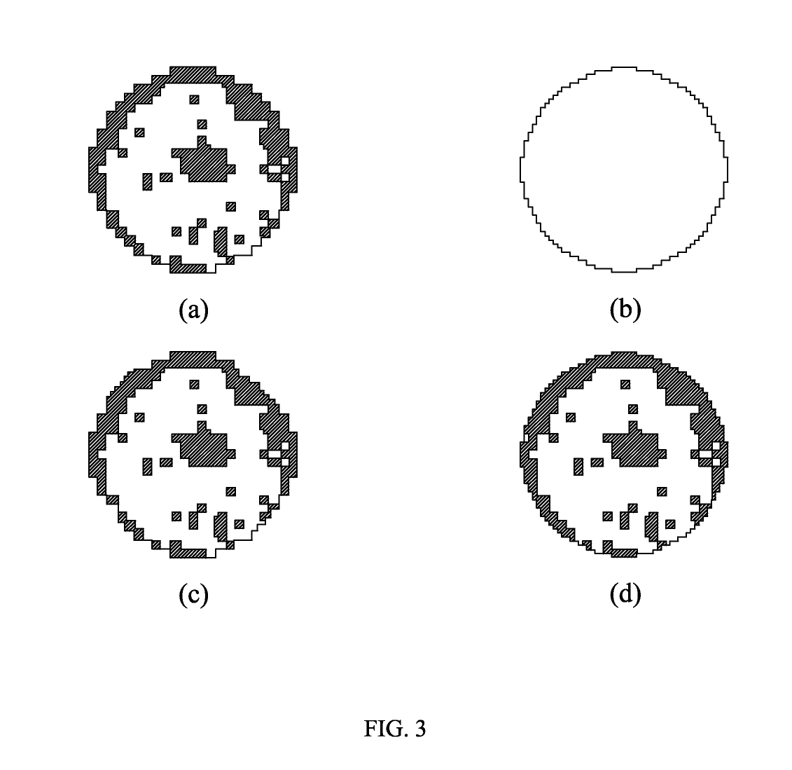

For example, the standardization module sets the size of the standardized wafer bin map as 50, as shown in FIG. 3(a), constructing a template having a size of 50×50, as shown in FIG. 3(b). Mapping each die from the original wafer bin map onto the template having the size of 50×50, as shown in FIG. 3(c). Determining whether or not there are points unmapped. If there are points unmapped, patching the unmapped points through the voting mechanism. If all points are mapped, skipping the voting mechanism. Furthermore, if a size of the original wafer bin map is larger than a size of the template, or if the original wafer is oval shape during the standardization process, bin values on the edge of the wafer bin map may be lost. Therefore, the standardization module patches the edge of the wafer bin map and reassigns bin values in the outermost area to produce the standardized wafer bin map, as shown in FIG. 3(d).

The coordinate transformation module uses Cartesian coordinates to polar coordinates transformation to change the mapping angle of the standardized wafer bin maps, and maps the standardized wafer bin maps back to the Cartesian coordinate system to produce the standardized wafer bin maps having congruent defect patterns with specific mapping angles as s plurality of standardized comparison wafer bin maps. The first step is to map every point (x,y) on the original standardized wafer bin maps onto the polar coordinate system (r,θ) after subtracting the center point of the standardized wafer bin map (Xc,Yc). This can be expressed in the equations below:

$$θ = {tan}^{- 1} ( \frac{y - Yc}{x - Xc} )$$

$$r = \sqrt{{( x - Xc )}^{2} + {( y - Yc )}^{2}}$$

The second step is to revolve every point on the standardized wafer bin maps by θᵣ, wherein θᵣ is a predetermined angle given by a user. This can be expressed in the equations below:

x=r cos(θ+θᵣ)+Xc

y=r sin(θ+θᵣ)+Yc

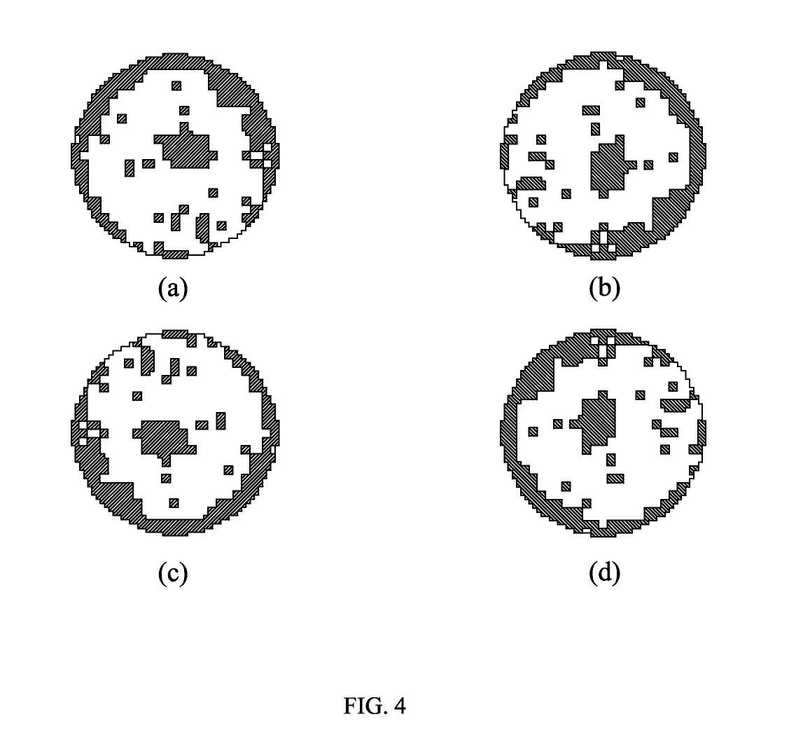

The last step is to transform from polar coordinates back to Cartesian coordinates and to produce the plurality of standardized comparison wafer bin maps. FIG. 4(a) through FIG. 4(d) are standardized comparison wafer bin maps derived from revolving the standardized wafer bin map in FIG. 3(d) by 90 degrees, 180 degrees, 270 degrees, and 360 degrees by the coordinate transformation system. However, the present invention is not limited to this embodiment, and the coordinate transformation module can revolve the standardized wafer bin map by any angle.

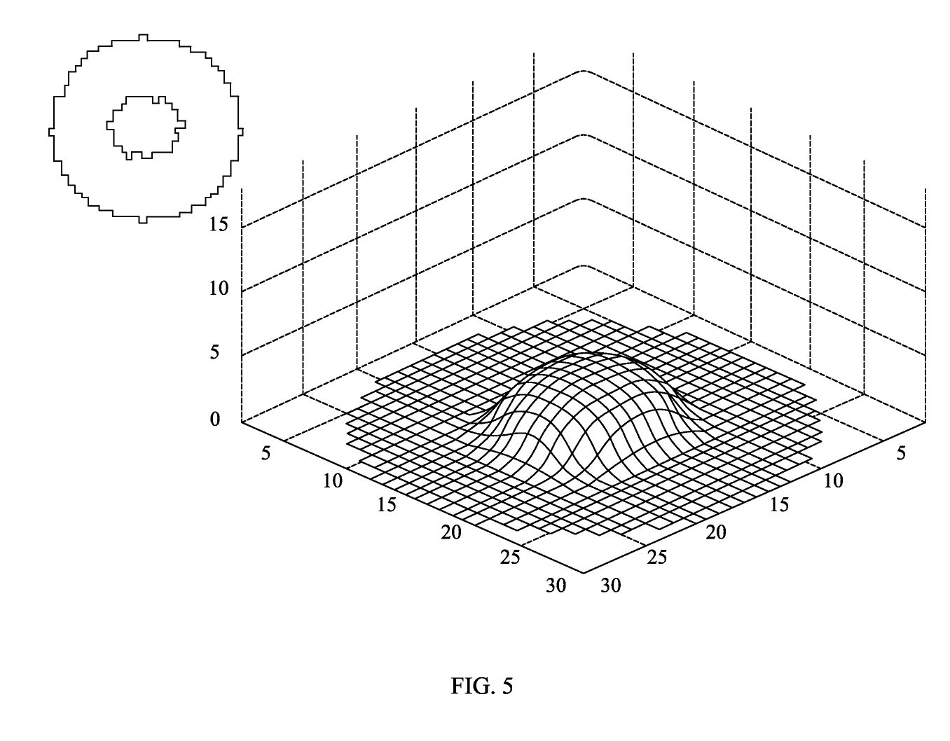

With reference to FIG. 5 for an exemplary diagram illustrating a defect density distribution of an analytic system of wafer bin map according to an embodiment of the present invention. Assigning a location of a bin as a data point j, a wafer bin map as a data set with a number of I, M(i) as the mountain function value of data I, y(i) as a good rate of wafer bin, which is a binary variables (defect: 0, good: 1), and d as a distance between a defect bin i and a defect bin j. m is a fixed parameter, and β is a reciprocal of variance. d_{jc} is a distance between a centroid c and a defect bin j, which is to normalize distances among every bin and central defect bin to eliminate a size effect. These can be expressed in the equations below:

$$β = {( \frac{{\sum }_{j} {d}_{jc}}{1} )}^{- 1}$$

$$M ( i ) = {\sum }_{j = 1}^{n} exp ( - m β ( 1 - y ( i ) ) {d}_{ij} ) , i = 1 , 2 , ⋯ , I$$

The closer the defect bins are to a center of defect patterns, the higher a defect density in the surrounding area is and the higher its peak value is. Therefore, the maximum peak value can be regarded as the center of defect patterns. On the contrary, the farther the defect bins are to the center of defect patterns, the lower the defect density in the surrounding area is and the lower its peak value is. For wafer bin maps without patterns, its peak value is close to 0. Therefore, defect density distributions of the plurality of standardized comparison wafer bin maps can be characterized.

A defect density characterization module conducts a data transformation to the plurality of standardized comparison wafer bin maps by a mountain function to produce a plurality of standardized feature wafer bin maps and to reveal their defect density distributions. Furthermore, a peak value of every bin is revealed as a comparison weight for the use of Weighted Modified Hausdorff Distance measurement to increase the accuracy of similarity comparison.

A test of randomness module uses a spatial test of randomness to downsize a plurality of historical wafer bin maps in the wafer bin map database because historical wafer bin maps of random patterns do not have analytical values but take up a large portion of wafer bin map database, which will have a huge effect on the system's computational efficiency. Therefore, sifting the historical wafer bin maps of systematic patterns into a similarity comparison module by the spatial test of randomness can decrease a number of compared samples and increase computational efficiency.

The test of randomness module uses Log Odds Ratio statistics to calculate defect relationships of adjacent bins on the historical wafer bin maps to examine whether or not a distribution of defective bins on the historical wafer bin maps is patterned. The steps of the test of randomness are described below:

Step 1: Test of Hypothesis

H₀: Defective bins on the historical wafer bin maps are randomly distributed,
H₁: Defective bins on the historical wafer bin maps are not randomly distributed.

Step 2: Test Statistics

$$log \hat{θ} = log \frac{( {N}_{GG} + 0.5 ) ( {N}_{BB} + 0.5 )}{( {N}_{BG} + 0.5 ) ( {N}_{GB} + 0.5 )} ∼ Normal ( 0 , σ )$$

$$σ = \sqrt{\frac{1}{( {N}_{GG} + 0.5 )} + \frac{1}{( {N}_{BG} + 0.5 )} + \frac{1}{( {N}_{GB} + 0.5 )} + \frac{1}{( {N}_{BB} + 0.5 )}}$$

Step 3: Test Rules

1. When the test statistics log \hat{θ} is close to 0, it can be inferred that the defective bins on the historical wafer bin maps are randomly distributed, i.e., random patterns.
2. When the test statistics log \hat{θ} is a large negative value, it can be inferred that the defective bins on the historical wafer bin maps are of discrete distribution, i.e., repetitive patterns, which are systematic defect patterns caused by using unmatched masks.
3. When the log \hat{θ} is a large positive value, it can be inferred that a significant clustering phenomenon has occurred, i.e., systematic patterns.

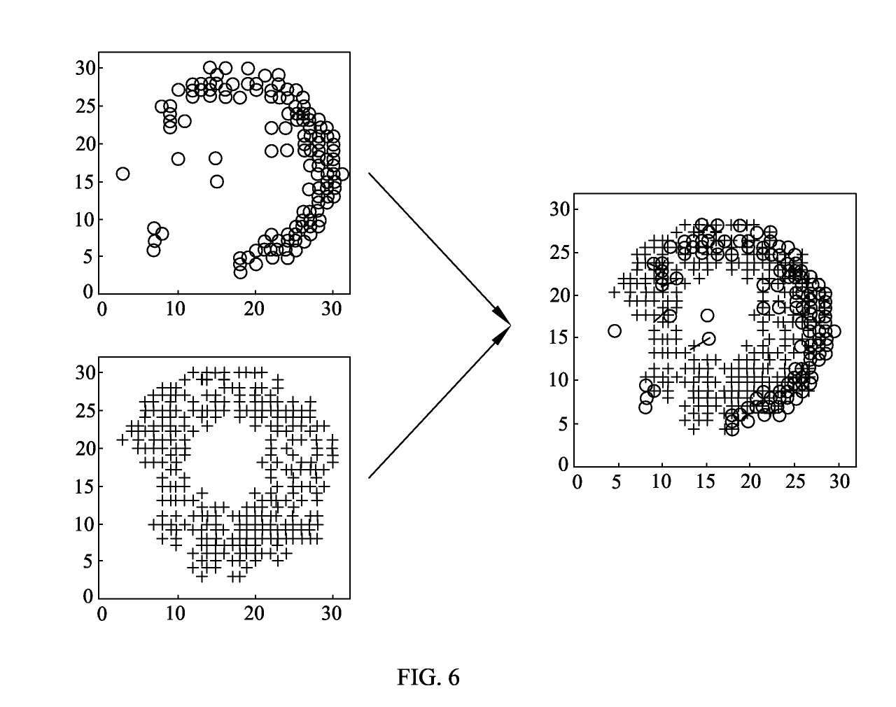

With reference to FIG. 6 for an exemplary diagram illustrating a similarity comparison process of an analytic system of wafer bin map according to an embodiment of the present invention. Distance measurement is commonly used as a method of similarity comparison in the field of image recognition. The similarity comparison module uses Weighted Modified Hausdorff Distance to retain spatial information without decreasing characteristic values to determine the degree of similarity of defect patterns between the standardized feature wafer bin maps corresponding to the plurality of historical wafer bin maps and the standardized feature wafer bin maps. The design of comparison weight and the definition of distance have significant effects on the results of comparison. The design of comparison weight sets a location of every bin as a center, searches for the peak values of 8 adjacent bins, and calculates a comparison weighted sum. This can be expressed in the equation below:

$${ω}_{ab} = {\sum }_{i ∈ ( - 1 , 0 , 1 ) , j ∈ ( - 1 , 0 , 1 )} \frac{\vert {mount}_{a ( x + i , y + j )} - {mount}_{b ( x + i , y + j )} \vert}{max ( {mount}_{a ( x + i , y + j )} , {mount}_{b ( x + i , y + j )} )}$$

Similarity comparison can be expressed in the equations below:

$$h ( A , B ) = \frac{1}{\# A} {\sum }_{a = 1}^{\# A} {min}_{b ∈ B} ( {ω}_{ab} \times {d}_{ab} )$$

$$h ( B , A ) = \frac{1}{\# B} {\sum }_{b = 1}^{\# B} {min}_{a ∈ A} ( {ω}_{ba} \times {d}_{ba} )$$

A and B in the equations above refer to two different standardized feature wafer bin maps, while a and b refer to defect bins on two different standardized feature wafer bin maps. h(A,B) refers to a distance of similarity between standardized feature wafer bin maps A and B, which is a sum of distances between all data points a in set A and the nearest data points in set B multiplying a weight and divided by a number of defect bins in set A. Similarly, h(B,A) refers to a distance of similarity between standardized feature wafer bin maps B and A. Choosing a maximum between h(A,B) and h(B,A) as a comparison number (S_{M}). This can be expressed in the equation below:

S_{M}=max(h(a,b),h(b,a))

To remove the interference from outliers and to emphasize the differences between two standardized feature wafer bin maps, assigning d_{md} as a maximum tolerable matching distance, i.e., only points within this distance can be compared. Points outside this distance are regarded as outliers, and are assigned the maximum tolerable matching distance d_{md} as a punishment. Therefore, a dissimilar number is a maximum of sum of comparison number and outlier punishment number (Sₒᵤₜ). This can be expressed in the equations below:

H(A,B)=S_{M(A,B)}+S_{out(A,B)}

H(B,A)=S_{M(B,A)}+S_{out(B,A)}

dissimilar number=max(H(A,B), H(B,A))

Therefore, the smaller the dissimilar number is, the larger the degree of similarity between two standardized feature wafer bin maps is. A pattern evaluation module uses the dissimilar number as a criterion of similarity comparison, and ranks the historical wafer bin maps based on the degree of similarity.

To evaluate a result of analysis, the pattern evaluation module adapts two commonly used evaluation indicators: Sensitivity and Specificity. The result of analysis is represented by a receiver operating characteristic curve, i.e., ROC curve. The pattern evaluation module ranks the historical wafer bin maps from the most similar to the least similar. Sensitivity is the ratio of historical wafer bin maps within rank N and evaluated as similar among all historical wafer bin maps which are evaluated as similar. Specificity is the ratio of historical wafer bin maps within rank N and evaluated as dissimilar among all historical wafer bin maps which are evaluated as dissimilar. The higher the Sensitivity and the Specificity are, the better the method of evaluation is. ROC curve can be drawn by taking Sensitivity as y axis and FN rate, i.e., 1-Specificity, as x axis to compare different methods of evaluation. This can be expressed in the definitions below:

True-positive(TP): similar patterns within rank N
True-negative(TN): similar patterns outside rank N
False-positive(FP): dissimilar patterns within rank N
False-negative(FN): dissimilar patterns outside rank N

Rank

| Result | within rank N | outside rank N |
|---|---|---|
| similar patterns | True-positive(TP) | True-negative(TN) |
| dissimilar patterns | False-positive(FP) | False -negative(FN) |

Sensitivity can be expressed in the equation below:

$$\frac{TP}{TP + TN} \times 100 \%$$

Specificity can be expressed in the equation below:

$$\frac{FP}{FP + FN} \times 100 \%$$

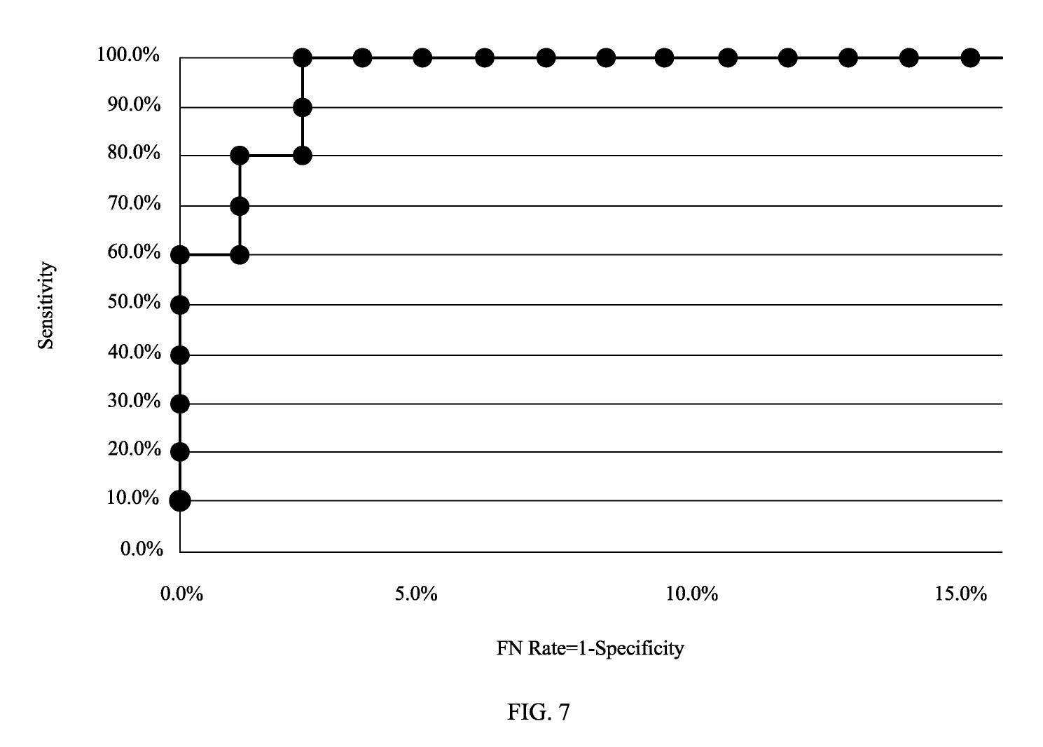

Therefore, the ROC curve can be drawn after ranking all the historical wafer bin maps from rank 1 to rank N. A ROC curve corresponding to the chart below is shown in FIG. 7.

| Rank N | Result | Sensitivity | Specificity |
|---|---|---|---|
| 1 | Similar | 10.0% | 100.0% |
| 2 | Similar | 20.0% | 100.0% |
| 3 | Similar | 30.0% | 100.0% |
| 4 | Similar | 40.0% | 100.0% |
| 5 | Similar | 50.0% | 100.0% |
| 6 | Similar | 60.0% | 100.0% |
| 7 | Dissimilar | 60.0% | 98.9% |
| 8 | Similar | 70.0% | 98.9% |
| 9 | Similar | 80.0% | 98.9% |
| 10 | Dissimilar | 80.0% | 97.8% |
| 11 | Similar | 90.0% | 97.8% |
| 12 | Similar | 100.0% | 97.8% |
| 13 | Dissimilar | 100.0% | 96.7% |
| 14 | Dissimilar | 100.0% | 95.6% |
| 15 | Dissimilar | 100.0% | 94.4% |

The pattern evaluation module defines an overall performance measurement indicator (PI) as a geometric mean of Sensitivity and Specificity. The Sensitivity and the Specificity are the best when the PI is at its maximum value. As far as the present embodiment is concerned, the maximum value of PI occurs at rank 12, where the Sensitivity is 100% and the Specificity is 97.8%. This can be expressed in the equation below:

PI=\sqrt{Sensitivity×Specificity}

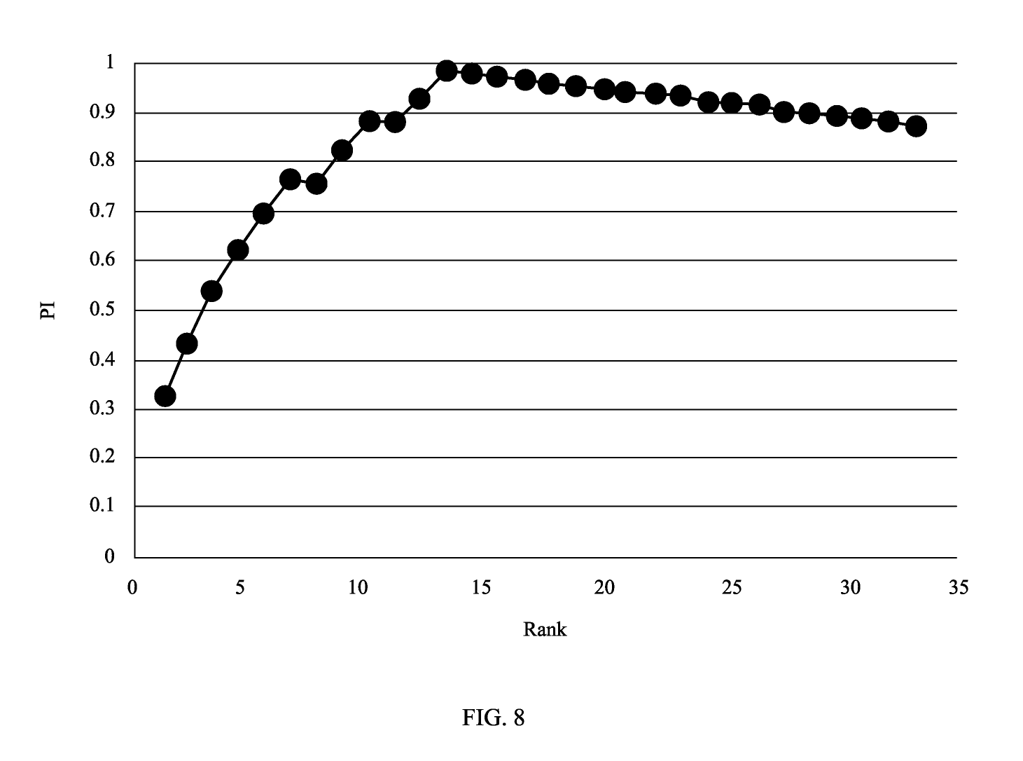

Next, making a graph with PI versus Rank, as shown in FIG. 8.

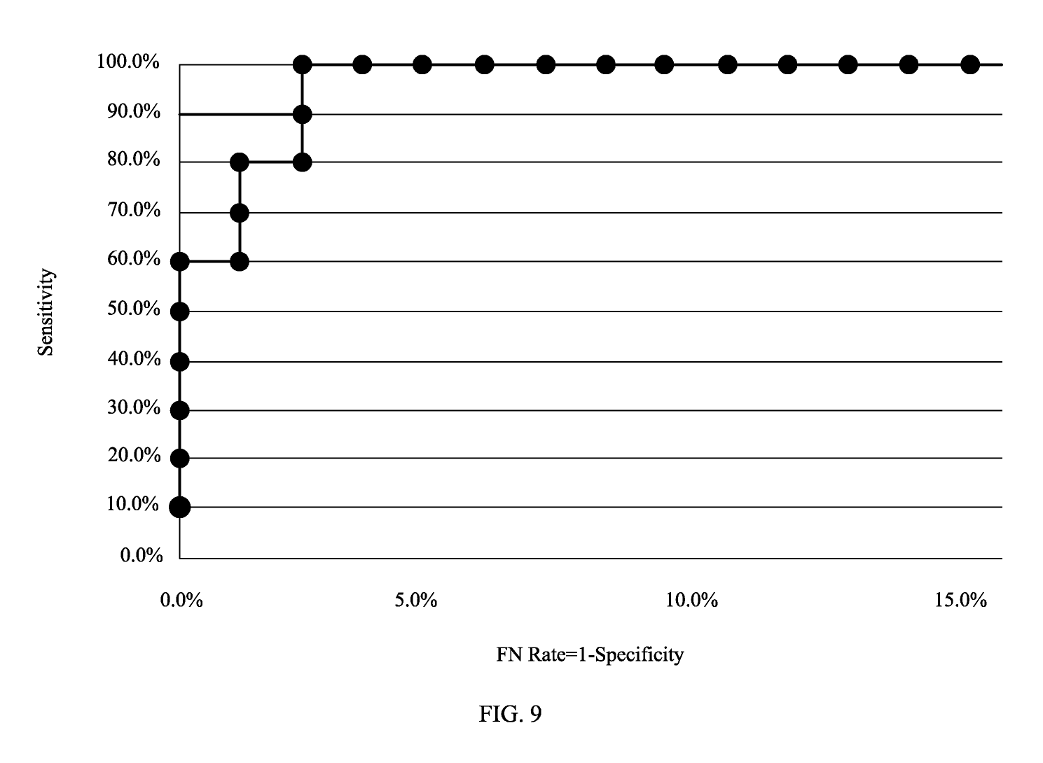

The pattern evaluation module evaluates a goodness of fit using a predetermined level of Sensitivity and Specificity given by a user. As described in the table above, when the predetermined Sensitivity is larger than 90%, i.e., when the pattern evaluation module detects wafer bin maps with 90% similarity, the Specificity in this case is 97.8%, as shown in FIG. 9.

When the level of Sensitivity given by the user is higher than 90% and the Specificity given by the user is higher than 95%, the pattern valuation module meets the criteria set by the user and does not need to adjust systematic parameters and design methodology. On the contrary, if the pattern evaluation module does not meet the criteria set by the user, weight design and calculation method need to be adjusted.

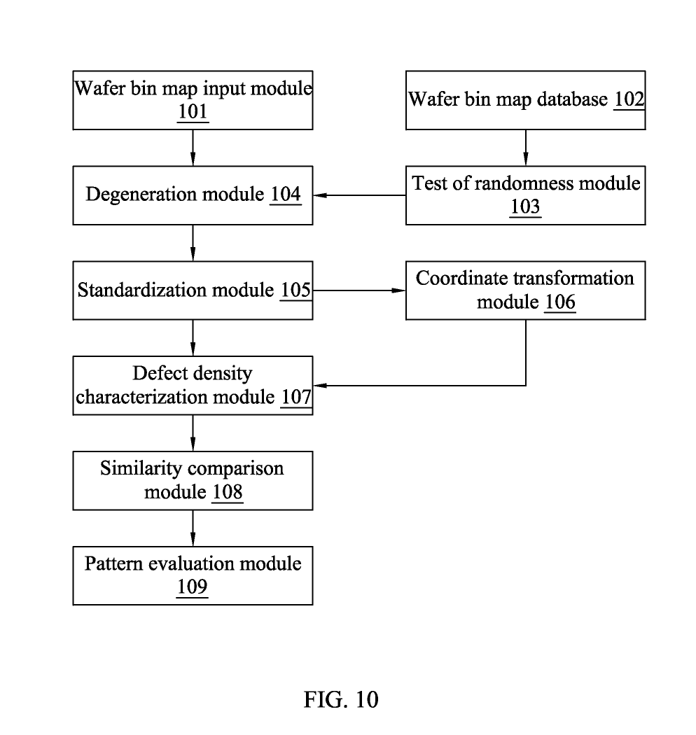

With reference to FIG. 10 for a block diagram of an analytic system of wafer bin map according to an embodiment of the present invention, the analytic system of wafer bin map includes a wafer bin map input module 101, a wafer bin map database 102, a test of randomness module 103, a degeneration module 104, a standardization module 105, a coordinate transformation module 106, a defect density characterization module 107, a similarity comparison module 108, and a pattern evaluation module 109.

The wafer bin map input module 101 provides a wafer bin map. The wafer bin map database 102 stores a plurality of historical wafer bin maps. The test of randomness module 103 implements a test of randomness to the plurality of historical wafer bin maps and removes the plurality of historical wafer bin maps of random patterns to decrease a compared number of the plurality of historical wafer bin maps. The degeneration module 104 degenerates the wafer bin map to simplify the wafer bin map. The standardization module 105 constructs a standardized wafer bin map. The coordinate transformation module 106 transforms the coordinates of the standardized wafer bin map to produce a plurality of standardized comparison wafer bin maps. The defect density characterization module 107 characterizes a defect density of the plurality of standardized comparison wafer bin maps to reveal a defect density distribution of the plurality of the standardized comparison wafer bin maps and to produce a plurality of standardized feature wafer bin maps. The similarity comparison module 108 compares the plurality of standardized feature wafer bin maps with a plurality of standardized feature wafer bin maps corresponding to the plurality of historical wafer bin maps. The pattern evaluation module 109 evaluates a possible match between the standardized wafer bin map and the plurality of historical wafer bin maps, and produces an evaluation result ranking the plurality of historical wafer bin maps according to similarity, sensitivity, and specificity.

Furthermore, the plurality of standardized feature wafer bin maps corresponding to the plurality of historical wafer bin maps are constructed through the test of randomness module 103, the degeneration module 104, the standardization module 105, and the defect density characterization module 107 processing the plurality of historical wafer bin maps.

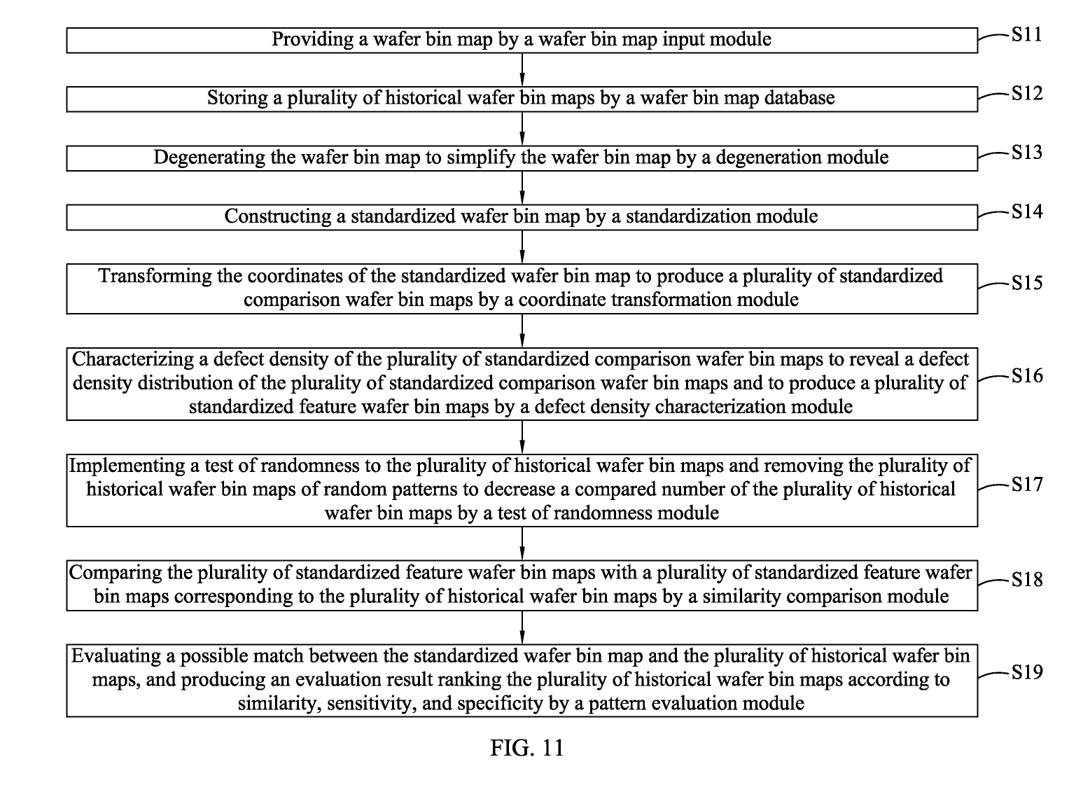

With reference to FIG. 11 for a flowchart of a wafer bin map analyzing process according to an embodiment of the present invention. In step S11, providing a wafer bin map by a wafer bin map input module, move on to step S12. In step S12, storing a plurality of historical wafer bin maps by a wafer bin map database, move on to step S13. In step S13, degenerating the wafer bin map to simplify the wafer bin map by a degeneration module, move on to step S14. In step S14, constructing a standardized wafer bin map by a standardization module, move on to step S15. In step S15, transforming the coordinates of the standardized wafer bin map to produce a plurality of standardized comparison wafer bin maps by a coordinate transformation module, move on to step S16. In step S16, characterizing a defect density of the plurality of standardized comparison wafer bin maps to reveal a defect density distribution of the plurality of standardized comparison wafer bin maps and to produce a plurality of standardized feature wafer bin maps by a defect density characterization module, move on to step S17. In step S17, implementing a test of randomness to the plurality of historical wafer bin maps and removing the plurality of historical wafer bin maps of random patterns to decrease a compared number of the plurality of historical wafer bin maps by a test of randomness module, move on to step S18. In step S18, comparing the plurality of standardized feature wafer bin maps with a plurality of standardized feature wafer bin maps corresponding to the plurality of historical wafer bin maps by a similarity comparison module, move on to step S19. In step S19, evaluating a possible match between the standardized wafer bin map and the plurality of historical wafer bin maps, and producing an evaluation result ranking the plurality of historical wafer bin maps according to similarity, sensitivity, and specificity by a pattern evaluation module.

The above drawings and detailed description of the present invention are provided as examples of the present invention, not for limiting purposes. Various changes in form and details may be made therein without departing from the spirit and scope of the present invention as defined by the following claims.

What is claimed is:

1. An analytic system of wafer bin map, comprising:
a wafer bin map input module, providing a wafer bin map;
a wafer bin map database, storing a plurality of historical wafer bin maps;
a degeneration module, degenerating the wafer bin map to simplify the wafer bin map;
a standardization module, constructing a standardized wafer bin map;
a coordinate transformation module, transforming the coordinates of the standardized wafer bin map to produce a plurality of standardized comparison wafer bin maps;
a defect density characterization module, characterizing a defect density of the plurality of standardized comparison wafer bin maps to reveal a defect density distribution of the plurality of standardized comparison wafer bin maps and to produce a plurality of standardized feature wafer bin maps;
a test of randomness module, implementing a test of randomness to the plurality of historical wafer bin maps and removing the plurality of historical wafer bin maps of random patterns to decrease a compared number of the plurality of historical wafer bin maps;
a similarity comparison module, comparing the plurality of standardized feature wafer bin maps with a plurality of standardized feature wafer bin maps corresponding to the plurality of historical wafer bin maps; and
a pattern evaluation module, evaluating a possible match between the standardized wafer bin map and the plurality of historical wafer bin maps, and producing an evaluation result ranking the plurality of historical wafer bin maps according to similarity, sensitivity, and specificity.

2. The analytic system of wafer bin map of claim 1, wherein degenerating the wafer bin map is to calculate a defective weighted sum for each position on the wafer bin map to determine whether or not each position on the wafer bin map is defective.

3. The analytic system of wafer bin map of claim 1, wherein the standardization module maps the wafer bin map to a template, and produces the standardized wafer bin map through a voting mechanism for patching the wafer bin map.

4. The analytic system of wafer bin map of claim 1, wherein the standardized wafer bin map undergoes a polar coordinates transformation and gradually revolves at a fixed angle to produce the plurality of standardized comparison wafer bin maps.

5. The analytic system of wafer bin map of claim 1, wherein the defect density characterization module transforms the plurality of standardized comparison wafer bin maps with a mountain function to reveal the defect density distribution of the plurality of standardized comparison wafer bin maps.

6. The analytic system of wafer bin map of claim 1, wherein the test of randomness module examines the plurality of historical wafer bin maps with log odds ratio and removes the plurality of historical wafer bin maps of random patterns to decrease the compared number of the plurality of historical wafer bin maps.

7. The analytic system of wafer bin map of claim 1, wherein the plurality of standardized feature wafer bin maps corresponding to the plurality of historical wafer bin maps are constructed through a processing of the test of randomness module, the degeneration module, the standardization module, and the defect density characterization module.

8. The analytic system of wafer bin map of claim 1, wherein the similarity comparison module conducts a similarity comparison through calculating a Hausdorff Distance and a comparison weighted sum.

9. A non-transitory computer readable media executing a wafer bin map analyzing process, the process comprises the following steps:
providing a wafer bin map by a wafer bin map input module;
storing a plurality of historical wafer bin maps by a wafer bin map database;
degenerating the wafer bin map to simplify the wafer bin map by a degeneration module;
constructing a standardized wafer bin map by a standardization module;
transforming the coordinates of the standardized wafer bin map to produce a plurality of standardized comparison wafer bin maps by a coordinate transformation module;
characterizing a defect density of the plurality of standardized comparison wafer bin maps to reveal a defect density distribution of the plurality of standardized comparison wafer bin maps and to produce a plurality of standardized feature wafer bin maps by a defect density characterization module;
implementing a test of randomness to the plurality of historical wafer bin maps and removing the plurality of historical wafer bin maps of random patterns to decrease a compared number of the plurality of historical wafer bin maps by a test of randomness module;
comparing the plurality of standardized feature wafer bin maps with a plurality of standardized feature wafer bin maps corresponding to the plurality of historical wafer bin maps by a similarity comparison module; and
evaluating a possible match between the standardized wafer bin map and the plurality of historical wafer bin maps, and producing an evaluation result ranking the plurality of historical wafer bin maps according to similarity, sensitivity, and specificity by a pattern evaluation module.

10. The non-transitory computer readable media of claim 9, wherein degenerating the wafer bin map is to calculate a defective weighted sum for each position on the wafer bin map to determine whether or not each position on the wafer bin map is defective.

11. The non-transitory computer readable media of claim 9, wherein the standardization module maps the wafer bin map to a template, and produces the standardized wafer bin map through a voting mechanism for patching the wafer bin map.

12. The non-transitory computer readable media of claim 9, wherein the standardized wafer bin map undergoes a polar coordinates transformation and gradually revolves at a fixed angle to produce the plurality of standardized comparison wafer bin maps.

13. The non-transitory computer readable media of claim 9, wherein the defect density characterization module transforms the plurality of standardized comparison wafer bin maps with a mountain function to reveal the defect density distribution of the plurality of standardized comparison wafer bin maps.

14. The non-transitory computer readable media of claim 9, wherein the test of randomness module examines the plurality of historical wafer bin maps with log odds ratio and removes the plurality of historical wafer bin maps of random patterns to decrease the compared number of the plurality of historical wafer bin maps.

15. The non-transitory computer readable media of claim 9, wherein the plurality of standardized feature wafer bin maps corresponding to the plurality of historical wafer bin maps are constructed through a processing of the test of randomness module, the degeneration module, the standardization module, and the defect density characterization module.

16. The non-transitory computer readable media of claim 9, wherein the similarity comparison module conducts a similarity comparison through calculating a Hausdorff Distance and a comparison weighted sum.
